(19) United States
(12) Patent Application Publication
(10) Pub. No.: US 2026/0038613 A1
(43) Pub. Date: Feb. 5, 2026

(54) MEMORY DEVICE AND SENSING CURRENT AMPLIFICATION CIRCUIT

(71) Applicant: SK hynix Inc., Gyeonggi-do (KR)

(72) Inventors: Chang Hyun HAN, Gyeonggi-do (KR); Moon Soo SUNG, Gyeonggi-do (KR)

(21) Appl. No.: 19/187,840

(22) Filed: Apr. 23, 2025

(30) Foreign Application Priority Data
Aug. 2, 2024 (KR) 10-2024-0103174

(51) Int. Cl. G11C 16/34; G11C 16/24; G11C 16/30

(52) U.S. Cl. CPC G11C 16/3495; G11C 16/24; G11C 16/30

(57) ABSTRACT

Provided herein are a memory device and a sensing current amplification circuit. The memory device may include memory cells, a page buffer circuit connected to the memory cells through a bit line, and a control logic configured to control operations of the memory cells and the page buffer circuit. The page buffer circuit may include a sensing current amplification circuit connected to a sensing node that is connected to the bit line to which a cell current corresponding to the memory cells is applied. The sensing current amplification circuit may generate an amplified current corresponding to the cell current such that the amplified current flows on the sensing node.

### CROSS-REFERENCE TO RELATED APPLICATION

The present application claims priority under 35 U.S.C. § 119 (a) to Korean patent application number 10-2024-0103174 filed on Aug. 2, 2024, the entire disclosure of which is incorporated by reference herein.

### BACKGROUND

### 1. Field of Invention

Various embodiments of the present disclosure generally relate to a memory device, and more particularly to a memory device and a page buffer circuit for increasing a sensing current.

### 2. Description of Related Art

Memory devices are classified into a volatile memory device and a nonvolatile memory device. The volatile memory device is a memory device in which data is stored only when power is supplied and in which stored data is lost when the supply of power is interrupted. The nonvolatile memory device is a memory device in which stored data is retained even when the supply of power is interrupted.

As the number of memory cells included in a memory device increases, a memory cell stack increases. The memory device may perform a read operation or a verify operation using a cell current flowing through the memory cells. As the memory cell stack increases, the cell current may decrease. The performance of a sensing operation may be degraded due to the decreased cell current. In order to reduce or prevent the performance degradation of the memory device, there is a need to amplify the sensing current.

### SUMMARY

Various embodiments of the present disclosure are directed to a memory device and a pager buffer circuit, which increase a sensing current by applying an amplified current corresponding to a cell current to a sensing node.

An embodiment of the present disclosure may provide for a memory device. The memory device may include memory cells, a page buffer circuit connected to the memory cells through a bit line, and a control logic configured to control operations of the memory cells and the page buffer circuit, wherein the page buffer circuit includes a sensing current amplification circuit connected to a sensing node that is connected to the bit line to which a cell current corresponding to the memory cells is applied, and the sensing current amplification circuit generates an amplified current corresponding to the cell current such that the amplified current flows on the sensing node.

An embodiment of the present disclosure may provide for a page buffer circuit. The page buffer circuit may include a bit line connector configured to connect a bit line connected to memory cells to a clamping sensing node, the bit line connected to memory cells, a sensing node connector configured to connect the clamping sensing node to a sensing node, and a sensing current amplification circuit configured to generate an amplified current corresponding to an amplification result of a cell current applied through the bit line such that the amplified current flows on the sensing node.

An embodiment of the present disclosure may provide for a circuit. The circuit may include a sensing node coupled to a bit line and configured to sense a cell current toward the bit line, a first transistor coupled between the sensing node and the bit line, a second transistor coupled between the sensing node and a terminal for a core voltage, a sensing current amplification circuit including third and fourth transistors coupled in series between the sensing node and a ground terminal, a gate terminal of the fourth transistor coupled to the bit line. The second transistor is controlled such that the core voltage is applied to the sensing node during a precharge period, and the sensing current amplification circuit generates an amplified current by amplifying the cell current such that the amplified current flows on the sensing node during an evaluation period after the precharge period.

### BRIEF DESCRIPTION OF THE DRAWINGS

FIG. 1 is a diagram illustrating a memory device according to an embodiment of the present disclosure.

FIG. 2 is a diagram illustrating a page buffer circuit according to an embodiment of the present disclosure.

FIG. 3 is a diagram illustrating control signals applied to the page buffer circuit of FIG. 2 and a change in the voltage of a sensing node.

FIG. 4 is a diagram illustrating the operation timing of a current amplification circuit according to an embodiment of the present disclosure.

FIG. 5 is a diagram illustrating a current amplification circuit including a variable voltage source according to an embodiment of the present disclosure.

FIG. 6 is a diagram illustrating a current amplification circuit connected to a sensing node according to an embodiment of the present disclosure.

FIG. 7 is a diagram illustrating control signals applied to a page buffer circuit of FIG. 6 and a change in the voltage of a sensing node.

### DETAILED DESCRIPTION

Specific structural or functional descriptions in the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in this specification.

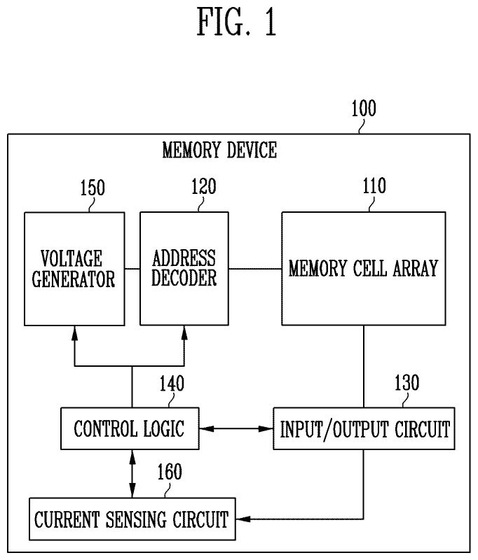

FIG. 1 is a diagram illustrating a memory device 100 according to an embodiment of the present disclosure.

Referring to FIG. 1, the memory device 100 may store data. The memory device 100 may include a memory cell array 110 including memory cells which store data, an address decoder 120 which decodes a column address, and an input and output (input/output) circuit 130 which transmits and receives data to and from an external system of the memory device 100. Further, the memory device 100 may include a control logic 140, a voltage generator 150 which generates a plurality of voltages having various voltage levels, and a current sensing circuit 160 which senses a sensing current flowing through a bit line during a verify operation.

Each of the memory cells included in the memory cell array 110 may be a single-level cell (SLC) which stores 1-bit data, or a memory cell which stores multi-bit data. The memory cell which stores the multi-bit data may be a multi-level cell (MLC) which stores 2-bit data, a triple-level cell (TLC) which stores 3-bit data, or a quad-level cell (QLC) which stores 4-bit data depending on the number of bits in the multi-bit data.

The address decoder 120 may be connected to the memory cell array 110 through word lines. The address decoder 120 may be operated under the control of the control logic 140.

The input/output circuit 130 may include page buffer circuits which read data stored in the memory cells and temporarily store the read data. The input/output circuit 130 may output the data, stored in the page buffer circuits, to the external system of the memory device 100, or may store data, received from the external system, in the page buffer circuits and then store the data in the memory cells. During a read operation and a verify operation, the page buffer circuits may supply the sensing current to bit lines connected to the memory cells to sense the threshold voltages of the memory cells. The page buffer circuits may sense a change in cell current determined depending on the program states of the memory cells through a sensing node, and may latch the sensed change as sensing data. The input/output circuit 130 may transfer the latched sensing data to the control logic 140. In an embodiment of the present disclosure, each of the page buffer circuits may include a sensing current amplification circuit which increases the sensing current that is applied to the sensing node. The sensing current amplification circuit may apply, to the sensing node, an amplified current proportional to a cell current.

The control logic 140 may control the overall operation of the memory device 100. The control logic 140 may generate control signals for controlling the address decoder 120, the input/output circuit 130, the voltage generator 150, and the current sensing circuit 160 so that a read operation, a program operation, and an erase operation are performed on the memory cell array 110. The control logic 140 may determine whether the result of program verification indicates a pass in response to a pass signal or a fail signal received from the current sensing circuit 160.

The voltage generator 150 may generate various voltages required for the operation of the memory device 100. The voltage generator 150 may generate a program voltage, a verify voltage, and a read voltage required by the memory device 100. The voltages generated by the voltage generator 150 may be supplied to the memory cell array 110 by the address decoder 120.

The current sensing circuit 160 may generate a reference current or a reference voltage based on an enable bit received from the control logic 140. The current sensing circuit 160 may generate a pass signal or a fail signal indicating a sensing result by comparing the generated reference voltage with a sensing voltage or by comparing the generated reference current with the sensing current.

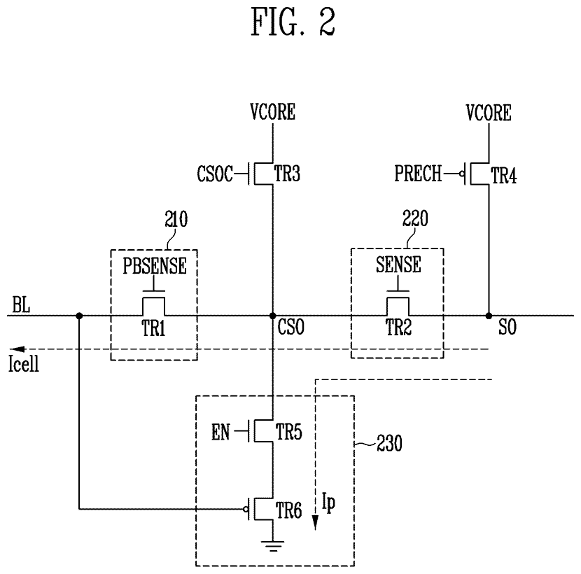

In an embodiment, the page buffer circuit may adjust the sensing current that is applied to the sensing node. Even if the magnitude of the cell current decreases with an increase in the number of memory cells included in the memory device 100, the sensitivity of the sensing operation may be improved by increasing the cell current. The page buffer circuit may include a sensing current amplification circuit, as shown in FIG. 2. The sensing current amplification circuit may increase the sensing current by applying, to the sensing node, a current amplified in proportion to the cell current. The increased sensing current enables the evaluation time of the sensing operation to be shortened, such that the performance of the sensing operation may be improved.

The control logic 140 may transfer, to the page buffer circuit, control signals for increasing the sensing current applied to the sensing node. The control signals transferred to the page buffer circuit may be voltage signals. The control logic 140 may amplify the amount of sensing current applied to the sensing node by adjusting the operations of transistors included in the page buffer circuit.

FIG. 2 is a diagram illustrating a page buffer circuit according to an embodiment of the present disclosure.

Referring to FIG. 2, one of the page buffer circuits included in the input/output circuit 130 of FIG. 1 may be shown. The page buffer circuit may be connected to memory cells through a bit line BL.

In FIG. 2, a clamping sensing node CSO may be connected to the bit line BL through a first transistor TR1, and may be connected to a sensing node SO through a second transistor TR2. The current sensing circuit 160 may perform a sensing operation based on a sensing current applied to the sensing node SO or the voltage of the sensing node SO. In an embodiment of the present disclosure, a bit line connector 210 may include the first transistor TR1, and a sensing node connector 220 may include the second transistor TR2. The first transistor TR1 and the second transistor TR2 may be NMOS transistors.

The sensing node SO may be connected to a terminal of a core voltage VCORE through a fourth transistor TR4. The clamping sensing node CSO may be connected to the terminal of the core voltage VCORE though a third transistor TR3. A precharge signal PRECH may be applied to a gate terminal of the fourth transistor TR4, and thus a precharge operation of applying the core voltage VCORE to the sensing node SO may be performed. A clamping sensing node control signal CSOC may be applied to the third transistor TR3, and thus the voltage level of the clamping sensing node CSO may be prevented from decreasing below a preset value. The clamping sensing node CSO may prevent the voltage of the bit line BL from fluctuating.

The clamping sensing node CSO may be connected to a sensing current amplification circuit 230. The sensing current amplification circuit 230 may include a fifth transistor TR5 and a sixth transistor TR6 connected in series. In an embodiment of the present disclosure, the third transistor TR3 and the fifth transistor TR5 may be NMOS transistors, and the fourth transistor TR4 and the sixth transistor TR6 may be PMOS transistors.

A cell current Icell corresponding to the memory cells may flow from the sensing node SO to the bit line BL. An amplified current Ip corresponding to the cell current Icell may flow from the sensing node SO to a ground terminal through the sensing current amplification circuit 230. In FIG. 2, the directions of the cell current Icell and the amplified current Ip are only examples and are not limited thereto. For example, the cell current Icell and the amplified current Ip may be applied to the sensing node SO.

The sensing current amplification circuit 230 may generate the amplified current Ip proportional to the cell current Icell such that the amplified current Ip flows from the sensing node SO to the ground terminal. Herein and below, the limitation “apply the amplified current Ip to the sensing node SO” represents the operation above by the sensing current amplification circuit 230. A gate terminal of the sixth transistor TR6 may be connected to the bit line. The sensing current flowing through the sensing node SO may be the sum of the cell current Icell and the amplified current Ip.

The transistors may be classified into long channel transistors and short channel transistors depending on the channel length that is the distance between source and drain terminals of each transistor. When the transistors are long channel transistors, the cell current Icell and the amplified current Ip are represented as follows:

$$Icell = μ n * C * Wn / Ln * {( Vref - Vbl - Vthn )}^{2} , and$$

$$Ip = μ p * C * Wn / Lp * {( Vbl - Vcso - Vthp )}^{2} .$$

In the Equation for the cell current Icell, μn may be the electron mobility coefficient of an NMOS transistor, C may be capacitance, Wn may be the area (width) of the NMOS transistor, and Ln may be the length of the NMOS transistor. Vref may be a reference voltage, and Vbl may be the voltage of the bit line BL. Vthn may be the threshold voltage of the NMOS transistor. According to the Equation above, the square root of the cell current Icell may be proportional to the voltage of the bit line BL.

In the Equation for the amplified current Ip, up may be the electron mobility coefficient of a PMOS transistor, C may be capacitance, Wp may be the area (width) of the PMOS transistor, and Lp may be the length of the PMOS transistor. Vbl may be the voltage of the bit line BL, and Vcso may be the voltage of the clamping sensing node CSO. Vthp may be the threshold voltage of the PMOS transistor. When the relationship between the cell current Icell and the amplified current Ip is summarized based on the above equations, the amplified current Ip may be proportional to the cell current Icell. That is, as the cell current Icell is greater, the amplified current Ip increases. Because the amplified current Ip is proportional to the cell current Icell, the sensing current that is the sum of the cell current Icell and the amplified current Ip may increase.

The cell current Icell and the amplified current Ip may be in proportion to each other even when the transistors are not long channel transistors. Because the amplified current Ip that increases as the cell current Icell is greater is applied to the sensing node SO, the sensing current may increase. In an embodiment of the present disclosure, regardless of the channel length of the transistors, the sensitivity of the sensing operation may increase as the sensing current increases.

In an embodiment of the present disclosure, the sensing current amplification circuit 230 may be connected to the sensing node SO or the clamping sensing node CSO. Various structures in which the sensing current amplification circuit 230 is capable of applying the amplified current Ip proportional to the voltage of the bit line BL to the sensing node SO may be embodiments of the present disclosure. The sensing current amplification circuit 230 may directly apply the amplified current Ip to the sensing node SO or may apply the amplified current Ip to the sensing node SO through the clamping sensing node CSO.

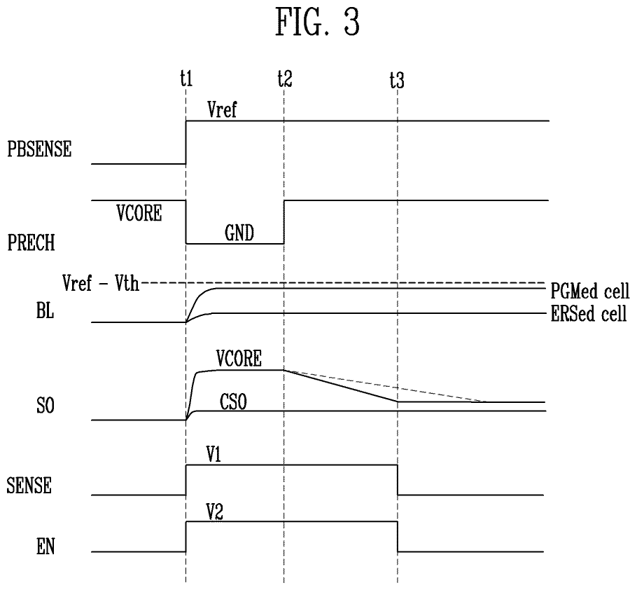

FIG. 3 is a diagram illustrating control signals applied to the page buffer circuit of FIG. 2 and a change in the voltage of a sensing node.

Referring to FIG. 3, voltages applied to the gate terminals of the first transistor TR1, the second transistor TR2, the fourth transistor TR4, and the fifth transistor TR5 and changes in the voltages of the bit line BL and the sensing node SO may be shown. The control logic 140 may apply control signals to the transistors, respectively.

The control logic 140 may apply a reference voltage Vref to the first transistor TR1 at a time point t1. The reference voltage Vref may be applied, and then the voltage of the bit line BL may converge to a voltage reduced from the reference voltage Vref by the threshold voltage of the first transistor TR1 (i.e., Vref-Vth). In detail, the cell current Icell of a programmed memory cell PGMed cell is less than the cell current Icell of an erased memory cell ERSed cell, and the voltage of the bit line BL of the programmed memory cell PGMed cell is greater than the voltage of the bit line BL of the erased memory cell ERSed cell.

The core voltage VCORE is applied to the sensing node SO at the time point t1, whereby the sensing node SO is precharged (i.e., a precharge period). The voltage level of the sensing node SO may increase up to the core voltage VCORE. At the time point t1, a turn-on voltage V1 (i.e., SENSE) may be applied to the second transistor TR2, and an enable voltage V2 (i.e., EN) may be applied to the fifth transistor TR5. By the turn-on voltage V1, the voltage of the clamping sensing node CSO at which the sixth transistor TR6 can be turned on may be formed. By the enable voltage V2, the voltage of the clamping sensing node CSO may be entirely transferred to the source terminal of the sixth transistor TR6.

By the fifth transistor TR5, the clamping sensing node CSO and the source terminal of the sixth transistor TR6 may be connected to each other, and the voltage of the bit line BL may be applied to the gate terminal of the sixth transistor TR6, whereby the amplified current Ip may be applied to the sensing node SO.

At a time point t2, the sensing node SO may be disconnected from the core voltage VCORE, and an evaluation operation may be performed based on a voltage drop at the sensing node SO. Depending on the magnitude of the sensing current applied to the sensing node SO, the speed at which the voltage of the sensing node SO decreases may vary. As the magnitude of the sensing current applied to the sensing node SO is greater, the speed at which the voltage of the sensing node SO decreases may be faster. The evaluation operation may be performed from the time point t2 to a time point t3 (i.e., evaluation period).

As the magnitude of the sensing current applied to the sensing node SO is lesser, the time required for the voltage of the sensing node SO to be decreased may increase. In FIG. 3, the slope of the voltage of the sensing node SO after the time point t2 may indicate the speed of the voltage drop at the sensing node SO. A solid line may indicate the case where the sensing current applied to the sensing node SO is increased by the sensing current amplification circuit 230, and a dotted line may indicate the voltage level of the sensing node SO of a page buffer circuit in which the sensing current amplification circuit 230 is not included. In the case where the sensing current increases, a time during which the evaluation operation is performed is short, and thus the performance of the memory device may be improved.

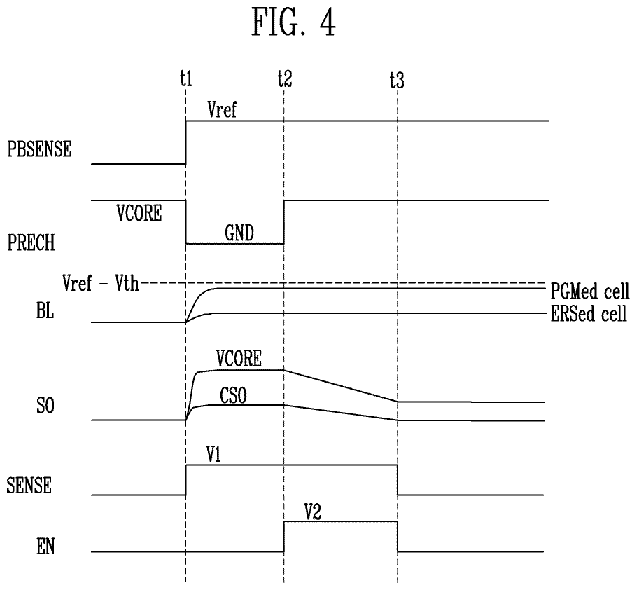

FIG. 4 is a diagram illustrating the operation timing of a current amplification circuit according to an embodiment of the present disclosure.

Referring to FIG. 4, a time during which the sensing current amplification circuit 230 operates may be determined depending on a time during which the enable voltage V2 (i.e., EN) is applied to the fifth transistor TR5. When the enable voltage V2 is not applied to the fifth transistor TR5, the amplified current Ip is not applied to the sensing node SO. In the description of FIG. 4, a portion corresponding to the description of FIG. 3 may be omitted.

In FIG. 4, after the time point t2, both the voltage of the sensing node SO and the voltage of the clamping sensing node CSO decrease. The amplified current Ip may be transferred to the sensing node SO through the clamping sensing node CSO after the time point t2.

In an embodiment of the present disclosure, the control logic 140 may set the time during which the enable voltage V2 (i.e., EN) is applied to the fifth transistor TR5 to a minimum time. While the sensing current amplification circuit 230 is applying the amplified current Ip to the sensing node SO, the sensing current flowing through the page buffer circuit increases, thereby increasing power consumption.

Because the time during which a sensing current greater than the cell current Icell is required at the sensing node SO is a period (i.e., evaluation period) from the time point t2 to the time point t3 in which the evaluation operation is performed, the sensing current amplification circuit 230 may apply the amplified current Ip to the sensing node SO only during the corresponding period. The time during which the sensing current increases may be minimized, thus reducing power consumption.

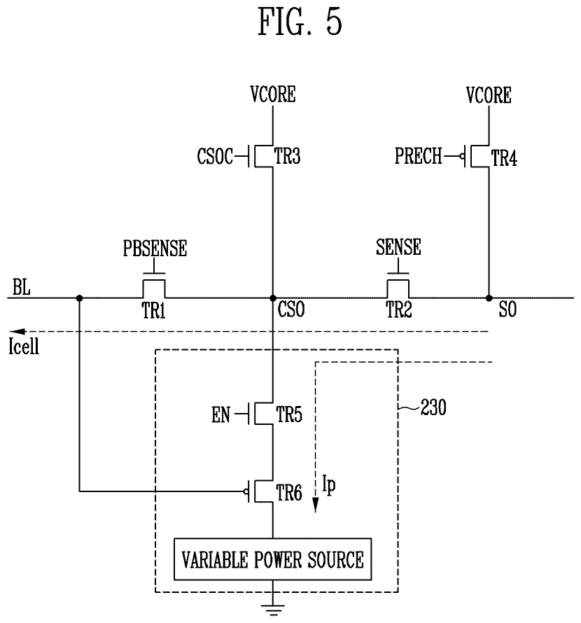

FIG. 5 is a diagram illustrating a sensing current amplification circuit including a variable voltage source according to an embodiment of the present disclosure.

Referring to FIG. 5, a variable power source included in the sensing current amplification circuit 230 may be a voltage source. The drain terminal of a sixth transistor TR6 included in the sensing current amplification circuit 230 may be connected to the variable voltage source connected to the ground terminal. In the description of FIG. 5, a portion corresponding to the description of FIGS. 3 and 4 may be omitted.

In an embodiment of the present disclosure, the case where the voltage of the variable voltage source is zero (0) V may correspond to the description of FIGS. 3 and 4. When the voltage of the variable voltage source is greater than 0 V, the magnitude of the amplified current Ip may decrease. When the voltage of the variable voltage source is less than 0 V, the magnitude of the amplified current Ip may increase.

By means of the variable voltage source, the margin of the amplified current Ip may be adjusted. In an embodiment of the present disclosure, the control logic 140 may control the voltage of the variable voltage source based on the magnitude of the cell current Icell. When the sensing current of a sensing node SO is greater than a preset reference value, the control logic 140 may increase the voltage of the variable voltage source. When the sensing current of the sensing node SO is less than the reference value, the control logic 140 may decrease the voltage of the variable voltage source.

In an embodiment of the present disclosure, the amplified current Ip may be changed in proportion to the cell current Icell, and may be adjusted by changing the voltage of the variable voltage source regardless of whether the cell current Icell increases or decreases. By the adjusted amplified current Ip, the magnitude of the sensing current of the sensing node SO may be determined. Depending on the magnitude of the sensing current, the speed of a voltage drop at the sensing node SO may be adjusted.

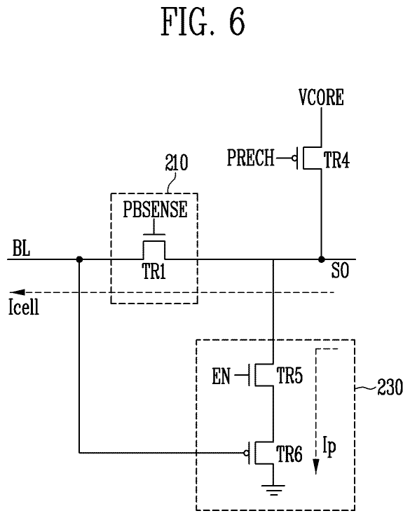

FIG. 6 is a diagram illustrating a current amplification circuit connected to a sensing node according to an embodiment of the present disclosure.

Referring to FIG. 6, a page buffer circuit may include a first transistor TR1 which connects a bit line BL to a sensing node SO, a fourth transistor TR4 which applies a core voltage VCORE to the sensing node SO, and a sensing current amplification circuit 230 which includes a fifth transistor TR5 and a sixth transistor TR6. A clamping sensing node may not be included in the page buffer circuit. For example, when the size of the page buffer circuit is limited, a page buffer circuit which does not include the clamping sensing node may be used. The size of the page buffer circuit which does not include the clamping sensing node may be smaller than the size of the page buffer circuit including the clamping sensing node. Compared to the circuit of FIG. 2 or FIG. 5, the clamping sensing node is not present, and thus the sensing node connector 220 may be omitted. In the description of FIG. 6, a portion corresponding to the description of FIG. 2 may be omitted.

The current amplification circuit 230 may directly apply an amplified current Ip proportional to the voltage of the bit line BL to the sensing node SO. The magnitude of the amplified current Ip applied to the sensing node SO may be determined depending on the width of the sixth transistor TR6. When the width of the sixth transistor TR6 becomes greater, the magnitude of the amplified current Ip may increase. When the width of the sixth transistor TR6 becomes lesser, the magnitude of the amplified current Ip may decrease.

When the widths of the sixth transistors TR6 in FIGS. 2 and 6 are identical to each other, the magnitude of the amplified current Ip applied to the sensing node SO in FIG. 6 may be greater than the magnitude of the amplified current Ip applied to the sensing node SO in FIG. 2. When a transistor having a width less than that of the sixth transistor TR6 in FIG. 2 is used as the sixth transistor TR6 in FIG. 6, the magnitude of the amplified current Ip applied to the sensing node SO in FIG. 6 may decrease. The sensing current applied to the sensing node SO increases due to the amplified current Ip, and thus the speed at which the voltage of the sensing node SO decreases may increase.

In FIG. 6, the voltage of the sensing node SO becomes less than a preset voltage, whereby the voltage of the bit line BL may fluctuate. Even if the voltage of the bit line BL fluctuates, the sensing current applied to the sensing node SO may be amplified, and thus the performance of the memory device may be improved.

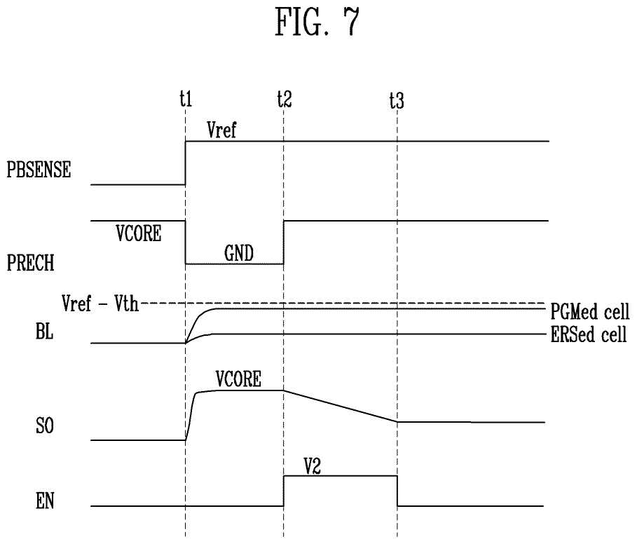

FIG. 7 is a diagram illustrating control signals applied to the page buffer circuit of FIG. 6 and a change in the voltage of a sensing node.

Referring to FIG. 7, the page buffer circuit may include the first transistor TR1 which connects the bit line BL to the sensing node SO, the fourth transistor TR4 which applies the core voltage VCORE to the sensing node SO, and the sensing current amplification circuit 230 which includes the fifth transistor TR5 and the sixth transistor TR6 coupled in series. Thus, an amplified current Ip may be applied to the sensing node SO by an enable voltage V2 applied to the fifth transistor TR5. In the description of FIG. 7, a portion corresponding to the description of FIG. 2 may be omitted.

The control logic 140 may apply the enable voltage V2 to the fifth transistor TR5 from a time point t2 to a time point t3. The sensing current amplification circuit 230 may apply the amplified current Ip to the sensing node SO by the enable voltage V2. The speed at which the voltage of the sensing node SO decreases may be determined based on the cell current Icell and the amplified current Ip which are applied to the sensing node SO.

According to embodiments of the present disclosure, there may be provided a memory device and a page buffer circuit, which enhance sensing sensitivity by increasing a sensing current applied to a sensing node, thus preventing the performance of a sensing operation from decreasing.

The scope of the present disclosure is defined by the accompanying claims, rather than by the detailed description, and all modifications or changes derived from the meaning and scope of the claims and equivalents thereof should be construed as falling within the scope of the present disclosure. Furthermore, the embodiments may be combined to form additional embodiments.

What is claimed is:

1. A memory device comprising:
memory cells;
a page buffer circuit connected to the memory cells through a bit line; and
a control logic configured to control operations of the memory cells and the page buffer circuit,
wherein the page buffer circuit comprises a sensing current amplification circuit connected to a sensing node that is connected to the bit line to which a cell current corresponding to the memory cells is applied, and
wherein the sensing current amplification circuit generates an amplified current corresponding to the cell current such that the amplified current flows on the sensing node.

2. The memory device according to claim 1, wherein the sensing current amplification circuit comprises:
an NMOS transistor and a PMOS transistor connected in series between the sensing node and a ground terminal.

3. The memory device according to claim 2, wherein a gate terminal of the PMOS transistor is connected to the bit line.

4. The memory device according to claim 2, wherein the NMOS transistor transfers a source voltage of the NMOS transistor to a source terminal of the PMOS transistor based on a gate voltage of the NMOS transistor.

5. The memory device according to claim 2, wherein:
the sensing node is connected to a clamping sensing node connected to the bit line through a first transistor.

6. The memory device according to claim 5, wherein a source terminal of the NMOS transistor is connected to the sensing node or the clamping sensing node.

7. The memory device according to claim 6, wherein the sensing current amplification circuit further comprises a variable voltage source connected between the PMOS transistor and the ground terminal.

8. The memory device according to claim 7, wherein a drain terminal of the PMOS transistor is connected to the variable voltage source that is capable of varying a voltage to be applied.

9. The memory device according to claim 8, wherein the amplified current increases or decreases depending on the voltage applied from the variable voltage source.

10. The memory device according to claim 1, wherein the amplified current is proportional to the cell current.

11. The memory device according to claim 4, wherein the control logic is configured to apply an enable voltage to a gate terminal of the NMOS transistor during an evaluation period in which the voltage of the sensing node decreases in response to a sensing current that is a sum of the cell current and the amplified current after a core voltage is interrupted.

12. The memory device according to claim 11, wherein the control logic is configured to apply the enable voltage to the gate terminal of the NMOS transistor during a precharge period in which the core voltage is applied to the sensing node.

13. A page buffer circuit comprising:
a bit line connector configured to connect a bit line to a clamping sensing node, the bit line connected to memory cells;
a sensing node connector configured to connect the clamping sensing node to a sensing node; and
a sensing current amplification circuit configured to generate an amplified current corresponding to an amplification result of a cell current applied through the bit line such that the amplified current flows on the sensing node.

14. The page buffer circuit according to claim 13, wherein the sensing current amplification circuit comprises an NMOS transistor and a PMOS transistor connected in series between the clamping sensing node and a ground terminal.

15. The page buffer circuit according to claim 14, wherein a source terminal of the NMOS transistor is connected to the clamping sensing node.

16. The page buffer circuit according to claim 14, wherein:
a gate terminal of the PMOS transistor is connected to the bit line, and
the amplified current is proportional to the cell current.

17. The page buffer circuit according to claim 16, wherein the NMOS transistor transfers a source voltage of the NMOS transistor to a source terminal of the PMOS transistor based on a gate voltage of the NMOS transistor.

18. The page buffer circuit according to claim 14, wherein the sensing current amplification circuit further comprises:
a variable voltage source connected between the PMOS transistor and the ground.

19. The page buffer circuit according to claim 18, wherein a drain terminal of the PMOS transistor is connected to the variable voltage source that is capable of varying a voltage to be applied.

20. The page buffer circuit according to claim 19, wherein the amplified current increases or decreases depending on the voltage applied from the variable voltage source.
